(19) United States
(12) Patent Application Publication
(10) Pub. No.: US 2026/0190817 A1
(43) Pub. Date: Jul. 2, 2026

(54) DISPLAY DEVICE, ELECTRONIC DEVICE INCLUDING THE SAME, AND METHOD FOR MANUFACTURING THE DISPLAY DEVICE

(71) Applicant: Samsung Display Co., LTD., Yongin-si (KR)

(72) Inventors: JINGOO KANG, Yongin-si (KR); DONGHOON KWAK, Yongin-si (KR); DAYOUNG LEE, Yongin-si (KR)

(21) Appl. No.: 19/240,470

(22) Filed: Jun. 17, 2025

(30) Foreign Application Priority Data
Dec. 30, 2024 (KR) 10-2024-0200876

(51) Int. Cl. H10K 59/80; H10K 59/12; H10K 59/122; H10K 59/126; H10K 59/38; H10K 102/00

(52) U.S. Cl. CPC H10K 59/8791; H10K 59/1201; H10K 59/122; H10K 59/126; H10K 59/38; H10K 59/873; H10K 2102/331

(57) ABSTRACT

A display device includes a substrate, a circuit layer, a light-emitting diode layer, an encapsulation layer, a color filter, a light-shielding portion, and a scattering layer. The light-emitting diode layer includes a light-emitting diode and a pixel defining layer. The encapsulation layer includes at least one of an inorganic film and an organic film. The color filter is disposed on the encapsulation layer. The light-shielding portion is disposed on the encapsulation layer and provides an aperture in which the color filter is disposed. The scattering layer is disposed on the light-shielding portion and the color filter and exposes at least a portion of the color filter. The scattering layer includes scattering particles. The scattering layer overlaps with the pixel defining layer, and at least a portion of the scattering layer does not overlap with the pixel defining layer and instead overlaps with the color filter.

This application claims priority to Korean Patent Application No. 10-2024-0200876, filed on Dec. 30, 2024, and all the benefits accruing therefrom under 35 U.S.C. § 119, the content of which is incorporated herein in its entirety by reference.

### BACKGROUND

### 1. Field

The disclosure relates to a display device and a method for manufacturing the display device, and specifically, to a display device including a scattering layer for reducing external light reflection and a method for manufacturing such a display device.

### 2. Description of the Related Art

A display device visually presents data on a screen to provide information to a user. One of the factors affecting the quality of the display device is the light incident from the external environment. When external light enters the display device, reflections may occur at various structural components of the display device, such as the light-emitting diode, pixel defining layer, and color filter. This reflection may degrade visibility and cause color distortion, possibly lowering the overall display quality.

To prevent quality degradation due to external light, techniques of adding scattering particles or a scattering layer are being studied to suppress the reflection of external light.

### SUMMARY

However, when scattering particles are added to the color filter material of the display device, not only is the reflected light scattered, but the light emitted from the organic light-emitting diode is also scattered, leading to a reduction in light-emission efficiency and an increase in scattering reflection to possibly result in deteriorated viewing experience.

A feature of the disclosure relates to address the aforementioned issues by providing a display device and a method for manufacturing the display device that may minimize the reduction in light-emission efficiency while reducing external light reflection. Specifically, a feature of the disclosure is directed to a display device and a method for manufacturing the display device, in which a scattering layer is formed with minimal overlap on the light-emitting area to improve display quality.

A display device in an embodiment of the disclosure may include a substrate, a circuit layer, a light-emitting diode layer, an encapsulation layer, a color filter, a light-shielding portion, and a scattering layer. The circuit layer may be disposed on the substrate. The light-emitting diode layer may be disposed on the circuit layer and may include a light-emitting diode and a pixel defining layer that defines an aperture in which the light-emitting diode is disposed. The encapsulation layer may be disposed on the light-emitting diode layer and may include at least one of an inorganic film and an organic film. The color filter may be disposed on the encapsulation layer. The light-shielding portion may be disposed on the encapsulation layer and may provide an aperture in which the color filter is disposed. The scattering layer may be disposed on the light-shielding portion and the color filter and may expose at least a portion of the color filter. The scattering layer may include scattering particles. The scattering layer may overlap with the pixel defining layer, and at least a portion of the scattering layer may not overlap with the pixel defining layer and instead overlap with the color filter.

In an embodiment, the scattering layer may overlap with the light-shielding portion, and at least a portion of the scattering layer may not overlap with the light-shielding portion and instead overlap with the color filter.

In an embodiment, the pixel defining layer may overlap with the light-shielding portion, and at least a portion of the pixel defining layer may not overlap with the light-shielding portion.

In an embodiment, the scattering layer may have the greatest thickness in a region overlapping with the light-shielding portion and non-overlapping with the color filter.

In an embodiment, the maximum thickness of the scattering layer in the region overlapping with the light-shielding portion may be greater than the maximum thickness of the scattering layer in the region overlapping with the color filter.

In an embodiment, the color filter may be convexly protruded in a display direction on the encapsulation layer.

In an embodiment, the scattering layer may be convexly protruded in the display direction on the light-shielding portion and the color filter.

In an embodiment, the scattering particles may include at least one selected from TiO₂, SiO₂, ZrO₂, HfO₂, ZnO, Al₂O₃, silica, and polymer particles.

A method for manufacturing a display device in an embodiment of the disclosure may include a preparation operation, a light-shielding portion formation operation, a color filter formation operation, and a scattering layer formation operation. The preparation operation may involve forming a preliminary display panel by forming a circuit layer, a light-emitting diode layer including a light-emitting diode and a pixel defining layer that defines an aperture in which the light-emitting diode is disposed, and an encapsulation layer on a substrate. The light-shielding portion formation operation may involve forming a light-shielding portion on the encapsulation layer to provide an aperture. The color filter formation operation may involve forming a color filter within the aperture of the light-shielding portion on the encapsulation layer. The scattering layer formation operation may involve forming a scattering layer on the light-shielding portion and the color filter to expose at least a portion of the color filter. The scattering layer may include scattering particles. The scattering layer may overlap with the pixel defining layer, and at least a portion of the scattering layer may not overlap with the pixel defining layer and instead overlap with the color filter.

In an embodiment, the color filter formation operation may involve ejecting and curing ink for a color filter including or consisting of a pigment or dye to form the color filter in the aperture of the light-shielding portion.

In an embodiment, the scattering layer formation operation may involve patterning a composition including or consisting of the scattering particles using a photoresist to form the scattering layer.

In an embodiment, the scattering layer formation operation may involve ejecting and curing ink including or consisting of scattering particles to form the scattering layer.

In an embodiment, the color filter formation operation may involve patterning a color filter composition including or consisting of a pigment or dye using a photoresist to form the color filter in the aperture of the light-shielding portion.

In an embodiment, the scattering layer formation operation may involve patterning a composition including or consisting of the scattering particles using a photoresist to form the scattering layer.

In an embodiment, the scattering layer formation operation may involve forming the scattering layer such that the scattering layer overlaps with the light-shielding portion and that at least a portion of the scattering layer does not overlap with the light-shielding portion and instead overlaps with the color filter.

In an embodiment, the light-shielding portion formation operation may involve forming the light-shielding portion such that the light-shielding portion overlaps with the pixel defining layer and that at least a portion of the pixel defining layer does not overlap with the light-shielding portion.

In an embodiment, the scattering layer formation operation may involve forming the scattering layer such that the scattering layer has the greatest thickness in a region overlapping with the light-shielding portion and non-overlapping with the color filter.

In an embodiment, the scattering layer formation operation may involve forming the scattering layer such that the maximum thickness of the scattering layer in the region overlapping with the light-shielding portion is greater than the maximum thickness of the scattering layer in the region overlapping with the color filter.

In another embodiment, the scattering particles may include at least one selected from TiO₂, SiO₂, ZrO₂, HfO₂, ZnO, Al₂O₃, silica, and polymer particles.

An electronic device in an embodiment of the disclosure may include a display module, a processor, a memory, and a power module. The display module may output image information based on an image data signal. The processor may execute an application to transfer the image data signal to the display module. The memory may store data information for executing the application. The power module may supply power to the display module, the processor, and the memory. The display module may include a substrate, a circuit layer, a light-emitting diode layer, an encapsulation layer, a color filter, a light-shielding portion, and a scattering layer. The circuit layer may be disposed on the substrate. The light-emitting diode layer may be disposed on the circuit layer and may include a light-emitting diode and a pixel defining layer that defines an aperture in which the light-emitting diode is disposed. The encapsulation layer may be disposed on the light-emitting diode layer and may include at least one of an inorganic film and an organic film. The color filter may be disposed on the encapsulation layer. The light-shielding portion may be disposed on the encapsulation layer and may provide an aperture in which the color filter is disposed. The scattering layer may be disposed on the light-shielding portion and the color filter and may expose at least a portion of the color filter. The scattering layer may include scattering particles. The scattering layer may overlap with the pixel defining layer, and at least a portion of the scattering layer may not overlap with the pixel defining layer and instead overlap with the color filter.

In an embodiment of the disclosure, by arranging a scattering layer on the light-emitting diode, pixel defining layer, and light-shielding portion, it is possible to suppress the reflection of external light and improve the quality of display.

Moreover, according to the disclosure, by forming an aperture in the scattering layer pattern over the light-emitting area, it is possible to maintain the light-emission efficiency while reducing the reflection of external light.

### BRIEF DESCRIPTION OF THE DRAWINGS

These and/or other features will become apparent and more readily appreciated from the following description of the embodiments, taken in conjunction with the accompanying drawings in which:

FIG. 1 is a plan view of an embodiment of a display device according to the disclosure;

FIG. 2 is a block diagram schematically illustrating an embodiment of the display device according to the disclosure;

FIG. 3 is an equivalent circuit diagram of a pixel shown in FIG. 2;

FIG. 4 is a cross-sectional view of the display device taken along line I-I′ of FIG. 1;

FIG. 5 is a plan view of an embodiment of a display panel according to the disclosure;

FIG. 6 is a cross-sectional view of the display panel taken along line II-II′ of FIG. 5;

FIG. 7 is a partial cross-sectional view illustrating an embodiment of a portion of the display panel according to the disclosure;

FIG. 8 is a diagram illustrating an embodiment of the scattering of external light according to the disclosure;

FIG. 9 is a partial cross-sectional view illustrating an embodiment of a portion of the display panel according to the disclosure;

FIG. 10 is a partial cross-sectional view illustrating another embodiment of a portion of the display panel according to the disclosure;

FIG. 11 illustrates a flow of a method for manufacturing an embodiment of a display device according to the disclosure;

FIGS. 12A to 12G are diagrams for illustrating an embodiment of the method for manufacturing a display device according to the disclosure;

FIG. 13 is a block diagram illustrating an embodiment of an electronic device incorporating the display device according to the disclosure; and

FIG. 14 illustrates schematic views of an embodiment of electronic devices incorporating the display device according to the disclosure.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

In the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, etc. illustrated in the drawings. The term “and/or” encompasses all possible combinations of the associated elements as defined.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the disclosure. Unless clearly used otherwise, any expressions in a singular form may include the meaning of a plural form.

In the disclosure, first to third directions DR1, DR2, DR3 may be defined in order to describe a display device in accordance with illustrative embodiments. The display device may include a display panel, which may be formed to include pixels in a plan view defined by the first direction DR1 and the second direction DR2. The third direction DR3 may be defined as the thickness direction of the display panel, and the first to third directions DR1, DR2, DR3 may be mutually orthogonal or intersecting.

The terms such as “processor” and “module” as used herein are intended to mean a hardware component such as a circuitry that performs a predetermined function. The hardware component may include a field-programmable gate array (“FPGA”) or an application-specific integrated circuit (“ASIC”), for example.

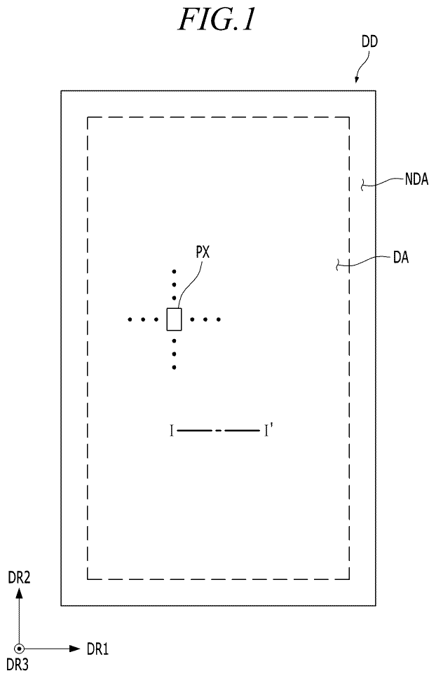

FIG. 1 is a plan view of an embodiment of a display device according to the disclosure. Referring to FIG. 1, display device DD may include a display panel (not shown), in which a display area DA and a non-display area NDA may be defined. The display area DA may display an image and may be arranged with a plurality of pixels PX that include light-emitting diodes, such as organic light-emitting diodes (“OLEDs”), to realize an image. Each pixel PX may include a thin-film transistor configured to control the light-emitting diodes. A single pixel PX may include at least one thin-film transistor. The non-display area NDA may surround the display area DA and may have a shape disposed on the outer side of the display area DA.

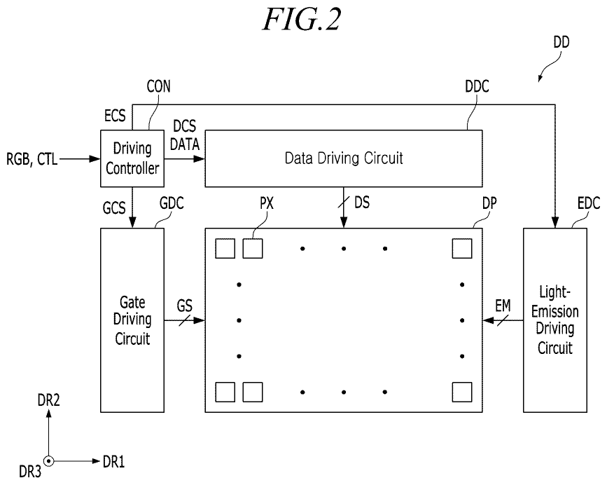

FIG. 2 is a block diagram schematically illustrating an embodiment of a display device according to the disclosure. Referring to FIG. 2, the display device DD includes a display panel DP, a gate driving circuit GDC, a light-emission driving circuit EDC, a data driving circuit DDC, and a driving controller CON. The display device DD is not limited to the configuration shown in FIG. 2 and may include additional components. In an embodiment, the display device DD may further include a voltage generator configured to generate voltages desired for components including the display panel DP, for example.

The driving controller CON receives an image signal RGB and a control signal CTL. In an embodiment, the image signal RGB and the control signal CTL may be provided by an application processor (not shown), for example. The image signal RGB may be understood as a graphical source of an image to be displayed on the display panel DP. The control signal CTL may include a synchronization signal to ensure that images are output at the correct positions on the display panel DP.

The driving controller CON generates an image data signal DATA by converting the data format of the image signal RGB according to the interface specifications of the data driving circuit DDC. Based on the control signal CTL, the driving controller CON may generate a gate control signal GCS for controlling the gate driving circuit GDC, a light-emission driving control signal ECS for controlling the light-emission driving circuit EDC, and a data control signal DCS for controlling the data driving circuit DDC.

The display panel DP includes pixels PX arranged two-dimensionally in a plan view defined by the first direction DR1 and the second direction DR2. The display panel DP is electrically connected to the gate driving circuit GDC via gate lines and to the light-emission driving circuit EDC via light-emission control lines. The gate lines and light-emission control lines may extend along the first direction DR1. The display panel DP is electrically connected to the data driving circuit DDC via data lines, which may extend along the second direction DR2.

The data driving circuit DDC receives the data control signal DCS and the image data signal DATA from the driving controller CON. The data driving circuit DDC converts the image data signal DATA, which is a digital signal, into data signals DS, which are analog signals. The data signals DS are converted to correspond to grayscale values of the image data signal DATA. The data driving circuit DDC outputs the converted data signals DS to the pixels PX through a plurality of data lines.

The gate driving circuit GDC receives the gate control signal GCS from the driving controller CON. The gate driving circuit GDC may output gate signals GS to the gate lines based on the gate control signal GCS. The gate driving circuit GDC may sequentially activate the plurality of pixels PX row by row through the gate signals GS. Here, activation refers to a state where the data signals DS may be input to the plurality of pixels PX through the data lines.

The light-emission driving circuit EDC receives the light-emission driving control signal ECS from the driving controller CON. The light-emission driving circuit EDC may output light-emission control signals EM to the light-emission control lines based on the light-emission driving control signal ECS. The light-emission driving circuit EDC may sequentially enable the plurality of pixels PX to emit light row by row through the light-emission control signals EM.

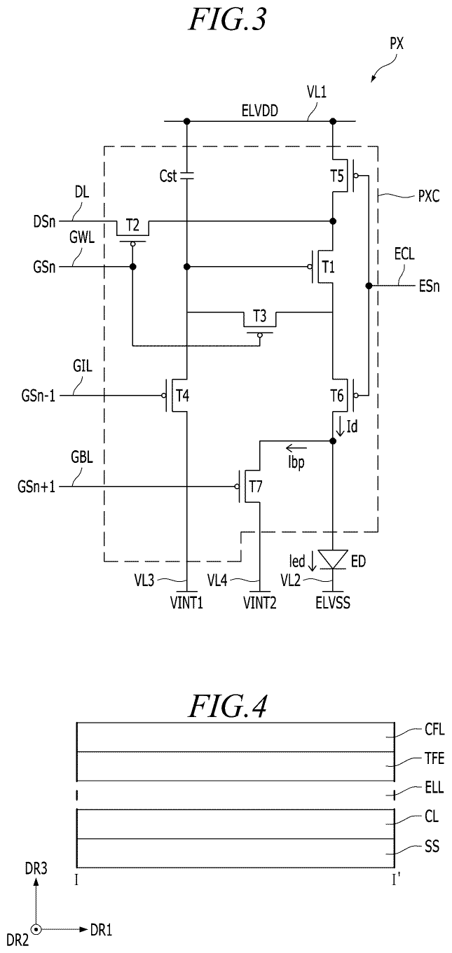

FIG. 3 is an equivalent circuit diagram of a pixel shown in FIG. 2. Referring to FIG. 3, the pixel PX is electrically connected to a data line DL, gate lines GWL, GIL, GBL (hereinafter also referred to as first gate line GIL, second gate line GWL, and third gate line GBL, respectively), and light-emission control lines ECL. The pixel PX corresponds to one of the plurality of pixels PX illustrated in FIG. 2.

The pixel PX receives a first driving voltage ELVDD, a second driving voltage ELVSS, a first initialization voltage VINT1, and a second initialization voltage VINT2. Although not explicitly shown, the first driving voltage ELVDD, the second driving voltage ELVSS, the first initialization voltage VINT1, and the second initialization voltage VINT2 may be supplied using voltages generated by a power management circuit of the display device DD, for example.

The pixel PX includes a pixel circuit PXC and a light-emitting diode ED. The pixel circuit PXC includes first through seventh transistors T1 to T7 and a single capacitor Cst. Each of the transistors T1 to T7 may be a P-type transistor having a low-temperature polycrystalline silicon (“LTPS”) semiconductor layer. However, the transistors T1 to T7 are not limited thereto and may be an N-type transistor using an oxide semiconductor as a semiconductor layer. Moreover, at least one of the transistors T1 to T7 may be an N-type transistor, while the remaining transistors may be P-type transistors. The circuit configuration and the number of transistors of the pixel PX are illustrative and are not limited to FIG. 3, and the configuration of the pixel circuit PXC may be embodied with various modifications.

The first transistor T1 supplies a driving current Id to the light-emitting diode ED based on the magnitude of a data signal DSn where n is a natural number. The second through seventh transistors T2 to T7 turn on or off such that the first transistor T1 receives the data signal DSn and supplies the driving current Id based on the magnitude of the data signal DSn. To this end, the gate electrodes of the second through seventh transistors T2 to T7 are connected to one of the first gate line GIL, the second gate line GWL, the third gate line GBL, and the light-emission control lines ECL.

The first transistor T1 includes a first electrode connected to a first driving voltage line VL1 via the fifth transistor T5, a second electrode electrically connected to the anode of the light-emitting diode ED via the sixth transistor T6, and a gate electrode connected to one end of the capacitor Cst. The first transistor T1 receives the data signal DSn transferred by the data line DL following the switching operation of the second transistor T2 and to supply the driving current Id to the light-emitting diode ED.

The second transistor T2 includes a first electrode connected to the data line DL, a second electrode connected to the first electrode of the first transistor T1, and a gate electrode connected to the second gate line GWL. The second transistor T2 turns on in response to a gate signal GSn (hereinafter referred to as second gate signal) transferred through the second gate line GWL and to transfer the data signal DSn received from the data line DL to the first electrode of the first transistor T1.

The third transistor T3 includes a first electrode connected to the gate electrode of the first transistor T1, a second electrode connected to the second electrode of the first transistor T1, and a gate electrode connected to the second gate line GWL. The third transistor T3 turns on in response to a second gate signal GSn transferred through the second gate line GWL and to connect the gate electrode and the second electrode of the first transistor T1 with each other, thereby diode-connecting the first transistor T1.

The fourth transistor T4 includes a first electrode connected to the gate electrode of the first transistor T1, a second electrode connected to a third voltage line VL3 through which the first initialization voltage VINT1 is supplied, and a gate electrode connected to the first gate line GIL. The fourth transistor T4 may turn on in response to a gate signal GSn−1 (hereinafter also referred to as first gate signal) transferred through the first gate line GIL and to perform an initialization operation by supplying the first initialization voltage VINT1 to the gate electrode of the first transistor T1, thereby resetting the voltage of the gate electrode of the first transistor T1.

The fifth transistor T5 includes a first electrode connected to the first driving voltage line VL1, a second electrode connected to the first electrode of the first transistor T1, and a gate electrode connected to a light-emission control line ECL. The sixth transistor T6 includes a first electrode connected to the second electrode of the first transistor T1, a second electrode connected to the anode of the light-emitting diode ED, and a gate electrode connected to the light-emission control line ECL. The fifth transistor T5 and the sixth transistor T6 turn on simultaneously in response to a light-emission control signal ESn transferred through the light-emission control line ECL. The first driving voltage ELVDD applied through the turned-on fifth transistor T5 is compensated via the first transistor T1 and may be supplied to the light-emitting diode ED.

The seventh transistor T7 includes a first electrode connected to the fourth voltage line VL4 through which the second initialization voltage VINT2 is supplied, a second electrode connected to the second electrode of the sixth transistor T6, and a gate electrode connected to the third gate line GBL. The seventh transistor T7 turns on in response to a gate signal GSn+1 (hereinafter referred to as third gate signal) transferred through the third gate line GBL. The second initialization voltage VINT2 applied through the turned-on seventh transistor T7 may initialize the anode of the light-emitting diode ED. A portion of the driving current Id bypasses through the seventh transistor T7 as a bypass current Ibp when the seventh transistor T7 is in an off-state.

One end of the capacitor Cst is connected to the gate electrode of the first transistor T1, as described above, and an opposite end is connected to the first driving voltage line VL1. The cathode of the light-emitting diode ED may be connected to the second driving voltage line VL2 that supplies the second driving voltage ELVSS.

The light-emitting diode ED may include a light-emitting material such as an organic light-emitting material, an inorganic light-emitting material, quantum dots, or quantum rods, for example. The light-emitting diode ED emit light based on an emission current Ied.

FIG. 4 is a cross-sectional view of the display device corresponding to line I-I′ of FIG. 1. Referring to FIG. 4, the display panel DP in an embodiment may include a substrate SS, a circuit layer CL, a light-emitting diode layer ELL, an encapsulation layer TFE, and a color filter layer CFL, which may be sequentially stacked in the third direction DR3.

The substrate SS may be formed from various materials, such as glass, metal, or plastic. In an embodiment, the substrate SS may be a flexible substrate, for example.

The circuit layer CL is disposed on the substrate SS and may correspond to the pixel circuit PXC shown in FIG. 3. The circuit layer CL may include a buffer layer, a semiconductor layer, a gate insulation layer, a conductive layer, an inter-insulation layer, a circuit insulation layer, and a planarization layer (not shown). The pixel circuit PXC, which includes the first through seventh transistors T1 to T7 and the capacitor Cst shown in FIG. 3, is formed by these layers.

The light-emitting diode layer ELL is disposed on the circuit layer CL. The light-emitting diode layer ELL may include a light-emitting diode and a pixel defining layer.

The encapsulation layer TFE is disposed on the light-emitting diode layer ELL. The encapsulation layer TFE may include at least one of an inorganic film and an organic film. Additionally, the encapsulation layer TFE may include at least one inorganic encapsulation layer and at least one organic encapsulation layer. The encapsulation layer TFE may cover the light-emitting diode and may protect the light-emitting diode layer ELL from external oxygen or moisture.

The color filter layer CFL is disposed on the encapsulation layer TFE. The color filter layer CFL may include a light-shielding portion, a color filter, and a scattering layer. The scattering layer may include scattering particles.

FIG. 5 is a plan view of an embodiment of the display panel according to the disclosure. Referring to FIG. 5, the display panel DP may include a non-emission region NPXA and emission regions PXA-R, PXA-G, and PXA-B. Each of the emission regions PXA-R, PXA-G, and PXA-B may be a region where light generated by a light-emitting diode is emitted. Each of the emission regions PXA-R, PXA-G, and PXA-B may be a region defined by a pixel defining layer PDL. The non-emission region NPXA may correspond to a region where the pixel defining layer PDL is disposed. The emission regions PXA-R, PXA-G, and PXA-B may correspond to the pixel PX.

The respective areas of the emission regions PXA-R, PXA-G, and PXA-B may be different from one another and may have an area ratio different from that shown in FIG. 5. The first emission regions PXA-B and the third emission regions PXA-R may be alternately arranged in the first direction DR1 to constitute a first group PXG1. The second emission regions PXA-G may be arranged in the first direction DR1 to constitute a second group PXG2. The first group PXG1 and the second group PXG2 may be spaced apart from each other in the second direction DR2. As shown in FIG. 5, the arrangement structure of the emission regions PXA-R, PXA-G, and PXA-B may be, but not limited to, a PenTile® structure.

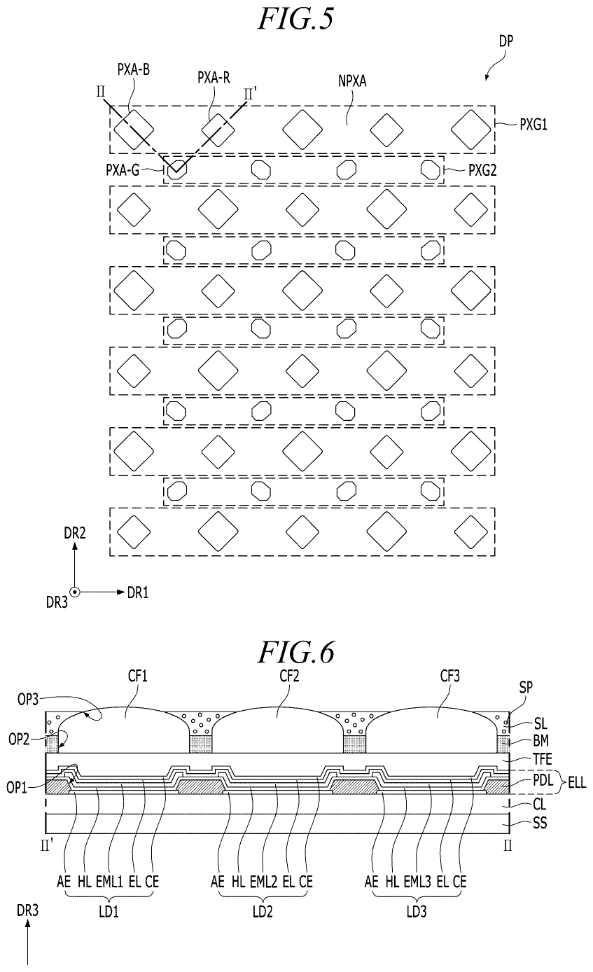

FIG. 6 is a cross-sectional view of the display panel corresponding to line II-II′ of FIG. 5. Referring to FIG. 6, the emission regions PXA-R, PXA-G, and PXA-B may correspond, respectively, to light-emitting diodes LD1, LD2, and LD3. The light-emitting diodes LD1, LD2, and LD3 may be included in the light-emitting diode layer ELL along with the pixel defining layer PDL. The light-emitting diodes LD1, LD2, and LD3 may be disposed on the circuit layer CL and may include an anode electrode AE, a hole control layer HL, a light-emitting layer EML, an electron control layer EL, and a cathode electrode CE.

The anode electrode AE of each of the light-emitting diodes LD1, LD2, and LD3 may be connected to a first electrode (not shown) or a second electrode (not shown) of a transistor disposed in the circuit layer CL and may be electrically connected to the transistor. The hole control layer HL may be disposed on the anode electrode AE to assist in the movement of holes generated at the anode electrode AE. In an embodiment, the hole control layer HL may have a structure further including a hole injection layer and a hole transport layer, for example.

Each of the light-emitting layers EML1, EML2, and EML3 may be disposed on the hole control layer HL and may emit light. The light-emitting layers EML1, EML2, and EML3 may include an organic light-emitting material or quantum dots. Accordingly, the light-emitting diodes LD1, LD2, and LD3 may be an OLED or a quantum dot light-emitting diode (“QLED”).

The electron control layer EL may be disposed on the light-emitting layers EML1, EML2, and EML3 to assist in the movement of electrons generated at the cathode electrode CE. In an embodiment, the electron control layer EL may have a structure further including an electron injection layer and an electron transport layer, for example.

The cathode electrode CE may be disposed on the electron control layer EL. The cathode electrode CE may have a relatively low resistance to facilitate current flow. Additionally, the cathode electrode CE may allow a portion of incident light to pass through while reflecting another portion.

The first light-emitting diode LD1, the second light-emitting diode LD2, and the third light-emitting diode LD3 may emit light at different wavelengths from the respective light-emitting layers EML1, EML2, and EML3. In an embodiment, the first light-emitting diode LD1 may emit red light, the second light-emitting diode LD2 may emit green light, and the third light-emitting diode LD3 may emit blue light, for example.

The pixel defining layer PDL may be disposed on the circuit layer CL. The pixel defining layer PDL may include or consist of a polymer resin. Additionally, the pixel defining layer PDL may be formed to include a light-absorbing material or to include a black pigment or black dye. The pixel defining layer PDL including or consisting of a black pigment or black dye may implement a black pixel defining layer.

The pixel defining layer PDL may define and separate individual pixels. A first opening area OP1 that exposes at least a portion of the anode electrode AE may be defined in the pixel defining layer PDL. The hole control layer HL may be disposed on the anode electrode AE exposed through the first opening area OP1, and the light-emitting layers EML1, EML2, and EML3 may be disposed on the hole control layer HL. The light-emitting layers EML1, EML2, and EML3 may be disposed within the first opening area OP1. The cathode electrode CE may be disposed on each of the light-emitting layers EML1, EML2, and EML3. The cathode electrode CE may be disposed entirely on the pixel defining layer PDL.

An encapsulation layer TFE may be disposed on the light-emitting diode layer ELL, and the encapsulation layer TFE may be disposed on the cathode electrode CE. The encapsulation layer TFE may include at least one of an inorganic film and an organic film. Additionally, the encapsulation layer TFE may include at least one inorganic encapsulation layer and at least one organic encapsulation layer. The inorganic encapsulation layer and the organic encapsulation layer may be alternately stacked. The encapsulation layer TFE may seal the light-emitting diodes LD1, LD2, and LD3 to protect the light-emitting diodes LD1, LD2, and LD3 from external oxygen or moisture.

A light-shielding portion BM may be disposed on the encapsulation layer TFE. The light-shielding portion BM may be a black matrix and may include or consist of an organic or inorganic light-shielding material including or consisting of a black pigment or dye. Moreover, the light-shielding portion BM may include a material capable of blocking light. The light-shielding portion BM may define and separate individual pixels along with the pixel defining layer PDL, and a second opening area OP2 overlapping the light-emitting diodes LD1, LD2, and LD3 may be defined in the light-shielding portion BM.

Color filters CF1, CF2, and CF3 may be disposed within the second opening area OP2 of the light-shielding portion BM. The color filters CF1, CF2, and CF3 may be spaced apart from each other and may be separated by the light-shielding portion BM. The color filters CF1, CF2, and CF3 may be disposed on the light-shielding portion BM in such a way that at least a portion thereof overlaps with the light-shielding portion BM. The color filters CF1, CF2, and CF3 may filter the light emitted from the light-emitting diodes LD1, LD2, and LD3 to allow the light to transmit externally, while also reducing the reflection of light incident from an external source.

The color filters CF1, CF2, and CF3 may include multiple colors corresponding to the emission regions of each pixel. In an embodiment, in the case where the first light-emitting diode LD1 emits light, the first color filter CF1 may filter red light, for example. When the second light-emitting diode LD2 emits light, the second color filter CF2 may filter green light. When the third light-emitting diode LD3 emits light, the third color filter CF3 may filter blue light.

A scattering layer SL may be disposed on the light-shielding portion BM and the color filters CF1, CF2, and CF3. The scattering layer SL may include scattering particles SP configured to change the traveling direction of light passing through the scattering layer SL without altering the color of the light. The scattering particles SP may include at least one of TiO₂, SiO₂, ZrO₂, HfO₂, ZnO, Al₂O₃, silica, and polymer particles. A third opening area OP3 that exposes at least a portion of the color filters CF1, CF2, and CF3 may be defined in the scattering layer SL. Accordingly, light emitted from the light-emitting diodes LD1, LD2, and LD3 may be transmitted externally through the third opening area OP3 of the scattering layer SL.

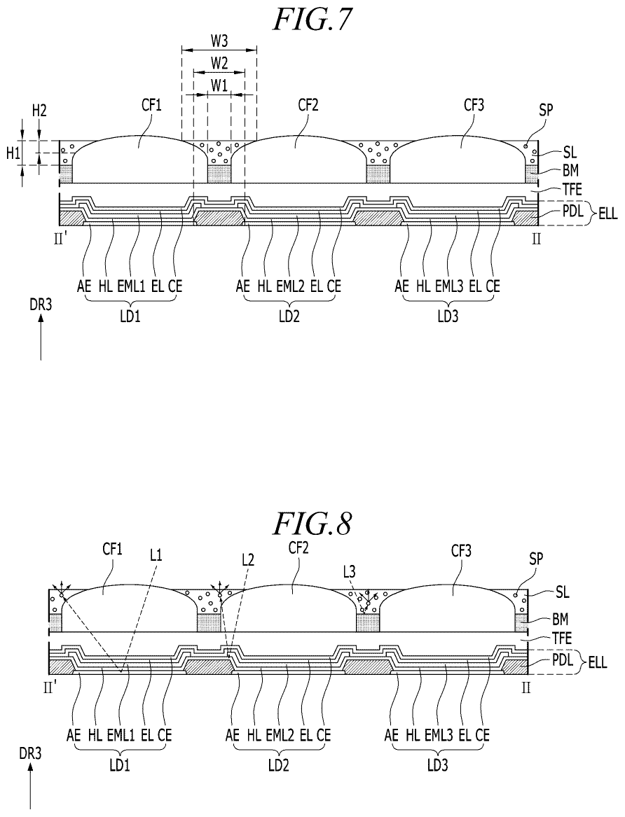

FIG. 7 is a partial cross-sectional view illustrating an embodiment of a portion of the display panel according to the disclosure. In FIGS. 7 to 10, layers below the light-emitting diode layer ELL are omitted for simplicity. Referring to FIG. 7, the scattering layer SL may cover at least a portion of the color filters CF1, CF2, and CF3 and the light-shielding portion BM. Moreover, the scattering layer SL may cover at least a portion of the light-emitting diodes LD1, LD2, and LD3 and the pixel defining layer PDL. The scattering layer SL may overlap with the light-shielding portion BM, and at least a portion of the scattering layer SL may not overlap with the light-shielding portion BM while overlapping with the color filters CF1, CF2, and CF3.

Accordingly, the scattering layer SL may include an aperture that exposes at least a portion of the color filters CF1, CF2, and CF3, and the width W3 of the scattering layer SL defined by the aperture may be greater than the width W1 of the light-shielding portion BM defined by the color filters CF1, CF2, and CF3 and the width W2 of the pixel defining layer PDL defined by the light-emitting layers EML1, EML2, and EML3. That is, the scattering layer SL may cover both the pixel defining layer PDL and the light-shielding portion BM and may also cover a region of the pixel defining layer PDL that is not covered by the light-shielding portion BM, as well as a region where the pixel defining layer PDL overlaps with the light-emitting diodes LD1, LD2, and LD3. The scattering layer SL may suppress the reflection of external light occurring at the light-emitting diodes LD1, LD2, and LD3 while maintaining the light-emission efficiency of the light-emitting diodes LD1, LD2, and LD3 through the aperture that exposes at least a portion of the color filters CF1, CF2, and CF3. Furthermore, the scattering layer SL may suppress the reflection of external light occurring at the pixel defining layer PDL and the light-shielding portion BM.

The width W2 of the pixel defining layer PDL defined by the light-emitting layers EML1, EML2, and EML3 may be greater than the width W1 of the light-shielding portion BM defined by the color filters CF1, CF2, and CF3. That is, the pixel defining layer PDL may overlap with the light-shielding portion BM, and at least a portion of the pixel defining layer PDL may not overlap with the light-shielding portion BM. Accordingly, the scattering layer SL may suppress the reflection of external light occurring at the pixel defining layer PDL. The width W1 of the light-shielding portion BM and the width W2 of the pixel defining layer PDL are not limited to an illustrative embodiment of the disclosure. The widths W1 and W2 may be equal, or the width W1 of the light-shielding portion BM may be greater than the width W2 of the pixel defining layer PDL.

With respect to the thickness of the scattering layer SL in the display direction (e.g., the third direction DR3), the thickness H1 in the region overlapping with the light-shielding portion BM may be greater than the thickness H2 in the region overlapping with the color filters CF1, CF2, and CF3. Accordingly, the scattering layer SL may minimize the reduction in light-emission efficiency of the light-emitting diodes LD1, LD2, and LD3 while scattering the reflections of external light.

Referring to FIG. 7, the color filters CF1, CF2, and CF3 may be formed using an inkjet printing technique. Accordingly, the color filters CF1, CF2, and CF3 may have a convex shape protruding in the display direction. The color filters CF1, CF2, and CF3 may have a curved surface where the center of curvature is disposed below the color filters CF1, CF2, and CF3. The distance between the center portion of the upper surface of the color filters CF1, CF2, and CF3 and the encapsulation layer TFE may be greater than the distance between the peripheral portions of the upper surface of the color filters CF1, CF2, and CF3 and the encapsulation layer TFE. That is, when viewed from the encapsulation layer TFE, the upper surface of the color filters CF1, CF2, and CF3 may have a concave shape. The scattering layer SL may be formed using a photolithography process. Accordingly, the maximum thickness of the scattering layer SL in the region overlapping with the light-shielding portion BM may be greater than the maximum thickness of the scattering layer SL in the region overlapping with the color filters CF1, CF2, and CF3.

FIG. 8 is a diagram illustrating an embodiment of the scattering of external light according to the disclosure. Referring to FIG. 8, among the externally incident light, light reflected from a light-emitting diode, e.g., first light L1 reflected from the first light-emitting diode LD1, may be scattered by the scattering layer SL. In the case where external light is reflected at the pixel defining layer PDL, e.g., second light L2 may be reflected at the pixel defining layer PDL and then scattered in the scattering layer SL. Additionally, when external light is reflected at the light-shielding portion BM, e.g., third light L3 may be reflected at the light-shielding portion BM and subsequently scattered in the scattering layer SL.

As the scattering layer SL is disposed to cover the light-shielding portion BM, the region where the light-shielding portion BM overlaps with the color filters CF1, CF2, and CF3, the pixel defining layer PDL, and the region where the pixel defining layer PDL overlaps with the light-emitting diodes LD1, LD2, and LD3, the scattering layer SL is capable of suppressing the reflection of external light occurring in the pixel defining layer PDL region that is not covered by the light-shielding portion BM, as well as in the region where the pixel defining layer PDL overlaps with the light-emitting diodes LD1, LD2, and LD3.

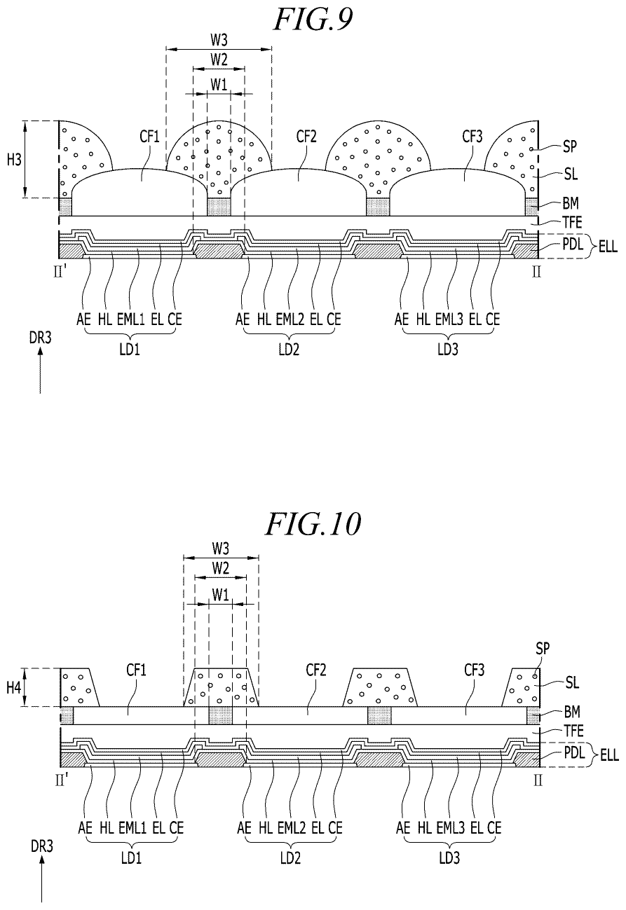

FIG. 9 is a partial cross-sectional view illustrating an embodiment of a portion of the display panel according to the disclosure. Referring to FIG. 9, the color filters CF1, CF2, and CF3 may be formed using an inkjet printing technique. Accordingly, the color filters CF1, CF2, and CF3 may have a convex shape protruding in the display direction. Additionally, the scattering layer SL may also be formed using an inkjet printing technique and may have a convex shape protruding in the display direction due to a surface energy difference with the underlying surface. The color filters CF1, CF2, and CF3 and the scattering layer SL may each have a curved surface whose center of curvature is disposed below the respective layer. When viewed from the light-shielding portion BM, the scattering layer SL may have a concave shape.

Even in the case where both the color filters CF1, CF2, and CF3 and the scattering layer SL are formed using an inkjet printing technique, the width W3 of the scattering layer SL may be greater than the width W2 of the pixel defining layer PDL and the width W1 of the light-shielding portion BM. Moreover, with respect to the thickness of the scattering layer SL in the display direction, the thickness H3 in the region overlapping with the light-shielding portion BM may be greater than the thickness in the region overlapping with the color filters CF1, CF2, and CF3.

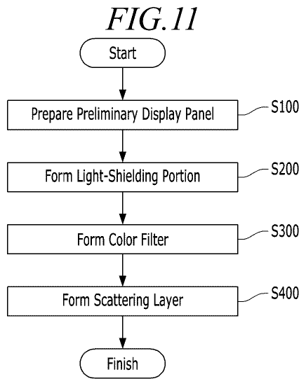

FIG. 10 is a partial cross-sectional view illustrating another embodiment of a portion of a display panel according to the disclosure. Referring to FIG. 10, the color filters CF1, CF2, and CF3 may be formed using a photolithography process. Moreover, the scattering layer SL may also be formed using a photolithography process.

Even when both the color filters CF1, CF2, and CF3 and the scattering layer SL are formed using a photolithography process, the width W3 of the scattering layer SL may be greater than the width W2 of the pixel defining layer PDL and the width W1 of the light-shielding portion BM. Additionally, with respect to the thickness of the scattering layer SL in the display direction, the thickness H4 in the region overlapping with the light-shielding portion BM may be greater than the thickness in the region overlapping with the color filters CF1, CF2, and CF3.

Referring to FIG. 11, a method for manufacturing a display device in an embodiment of the disclosure may include a preparation operation (S100), a light-shielding portion formation operation (S200), a color filter formation operation (S300), and a scattering layer formation operation (S400).

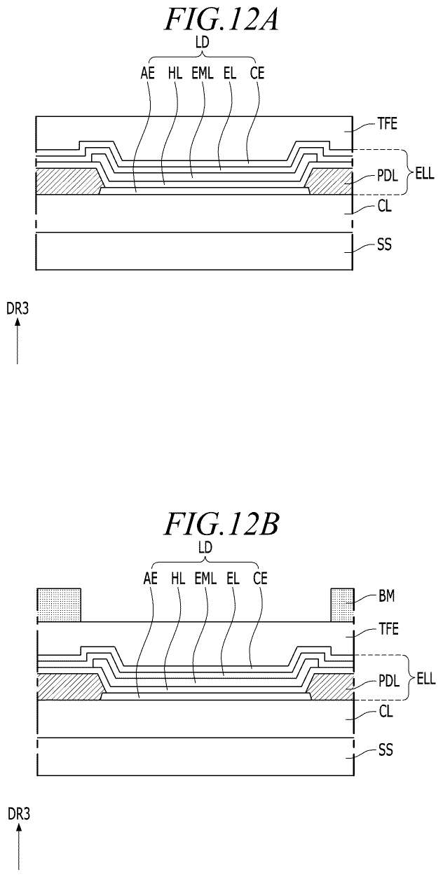

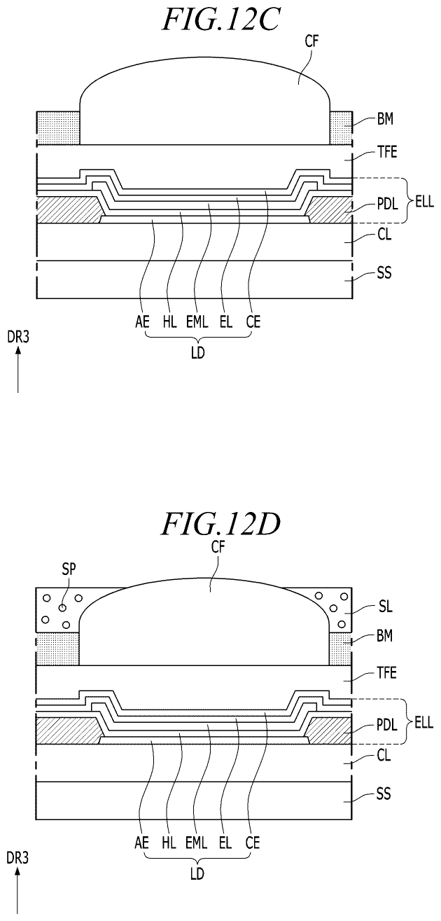

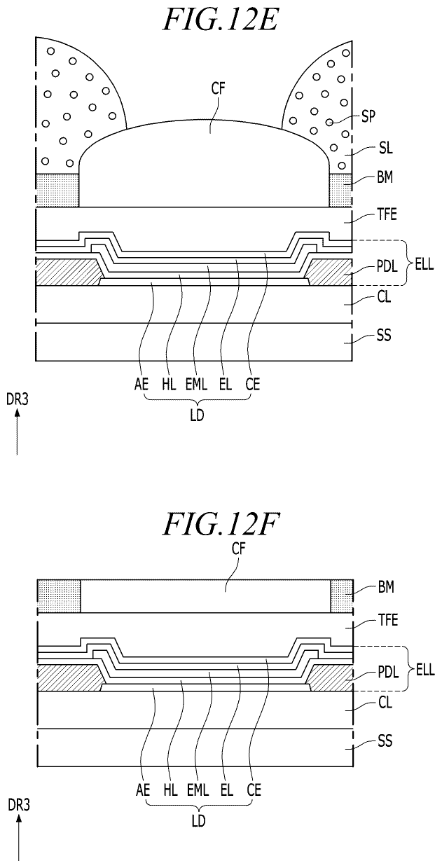

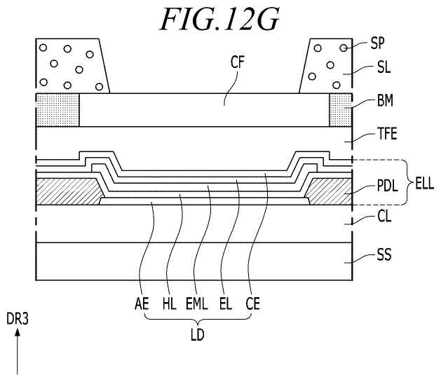

Referring to FIGS. 11 and 12A, in the preparation operation (S100), a preliminary display panel may be prepared by forming a circuit layer CL, a light-emitting diode layer ELL, and an encapsulation layer TFE on a substrate SS. The light-emitting diode layer ELL may include a light-emitting diode LD and a pixel defining layer PDL, and the pixel defining layer PDL may be formed to have an aperture that exposes a portion of the light-emitting diode LD.

Referring to FIGS. 11 and 12B, in the light-shielding portion formation operation (S200), a light-shielding portion BM may be formed on the encapsulation layer TFE of the preliminary display panel. The light-shielding portion BM may be formed to have an aperture that overlaps the light-emitting diode LD. The aperture of the light-shielding portion BM may overlap with the light-emitting diode LD. In an embodiment of the disclosure, the aperture of the light-shielding portion BM may be larger than the aperture of the pixel defining layer PDL. Accordingly, the pixel defining layer PDL may overlap with the light-shielding portion BM, and at least a portion of the pixel defining layer PDL may not overlap with the light-shielding portion BM. The size of the aperture of the light-shielding portion BM and the size of the aperture of the pixel defining layer PDL are not limited to what is described herein, and in some embodiments, the aperture of the light-shielding portion BM may be smaller than the aperture of the pixel defining layer PDL.

Referring to FIGS. 11, 12C, and 12F, in the color filter formation operation (S300), a color filter CF may be formed within the aperture of the light-shielding portion BM disposed on the encapsulation layer TFE. The color filter CF may be formed using an inkjet printing technique (refer to FIG. 12C) or a photolithography process (refer to FIG. 12F). In the case where the color filter CF is formed using an inkjet printing technique (refer to FIG. 12C), in the color filter formation operation (S300), color filter ink may be discharged into the aperture of the light-shielding portion BM and then cured using, e.g., ultraviolet (“UV”) radiation or heating to form the color filter CF. Accordingly, the color filter CF may have a convex shape protruding in the display direction. The color filter CF may have a curved surface where the center of curvature is disposed below the color filters CF1, CF2, and CF3. That is, the distance between the center portion of the upper surface of the color filter CF and the encapsulation layer TFE may be greater than the distance between the peripheral portion of the upper surface of the color filter CF and the encapsulation layer TFE. When viewed from the encapsulation layer TFE, the upper surface of the color filter CF may have a concave shape. In the case where the color filter CF is formed using a photolithography process (refer to FIG. 12F), after a photoresist is applied on a color filter composition including or consisting of a pigment or dye, exposure, development, curing, and etching processes may be performed to form the color filter CF.

Referring to FIGS. 11, 12D, 12E, and 12G, in the scattering layer formation operation (S400), a scattering layer SL may be formed on the light-shielding portion BM and the color filter CF. The scattering layer SL may be formed using an inkjet printing technique (refer to FIG. 12E) or a photolithography process (refer to FIGS. 12D and 12G). The scattering layer SL may include scattering particles SP, which may include at least one of TiO₂, SiO₂, ZrO₂, HfO₂, ZnO, Al₂O₃, silica, and polymer particles.

In the case where the scattering layer SL is formed using an inkjet printing technique (refer to FIG. 12E), in the scattering layer formation operation (S400), ink including or consisting of the scattering particles SP may be discharged onto the region overlapping with the light-shielding portion BM and the pixel defining layer PDL and then cured using, e.g., UV radiation or heating to form the scattering layer SL. Accordingly, the scattering layer SL may have a convex shape protruding in the display direction. The scattering layer SL may have a curved surface where the center of curvature is disposed below the scattering layer SL. When viewed from the light-shielding portion BM, the scattering layer SL may have a concave shape.

In the case where the scattering layer SL is formed using a photolithography process (refer to FIGS. 12D and 12G), after a photoresist is applied on a composition including or consisting of the scattering particles SP, exposure, development, curing, and etching processes may be performed to form the scattering layer SL.

Regardless of the processing technique for forming the color filter CF and the scattering layer SL, the scattering layer SL may include an aperture exposing at least a portion of the color filter CF and may cover both the light-shielding portion BM and the pixel defining layer PDL. The scattering layer SL may overlap with the light-shielding portion BM, and at least a portion of the scattering layer SL may not overlap with the light-shielding portion BM while overlapping with the color filter CF. Additionally, the scattering layer SL may have the greatest thickness in the region overlapping with the light-shielding portion BM and non-overlapping with the color filter CF.

The display device in embodiments of the disclosure may be applied to various electronic devices. An electronic device in an embodiment of the disclosure may include the display device described above and may further include modules or devices having other additional functions in addition to the display device.

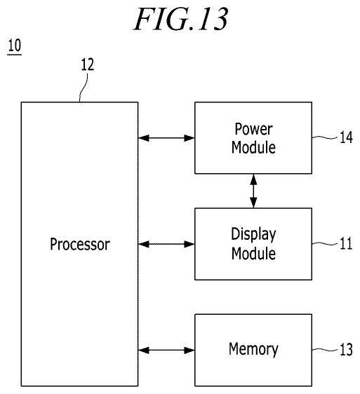

FIG. 13 is a block diagram of an embodiment of an electronic device according to the disclosure. Referring to FIG. 13, an electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Stored in the memory 13 may be data information desired for the operation of the processor 12 or the display module 11. When the processor 12 executes an application stored in the memory 13, an image data signal and/or an input control signal may be transferred to the display module 11, which may then process the received signal/signals and output image information through a display screen.

The power module 14 may include a power supply module, such as a power adapter or a battery device, and a power conversion module configured to convert the power supplied by the power supply module to generate power desired for the operation of the electronic device 10.

At least one of the components of the electronic device 10 described above may be included in the display device in the embodiments described herein. Moreover, some of the individual modules functionally included in a single module may be included in the display device, while others may be separately provided from the display device. In an embodiment, the display device may include the display module 11, whereas the processor 12, the memory 13, and the power module 14 may be provided as separate components within the electronic device 10 rather than as part of the display device, for example.

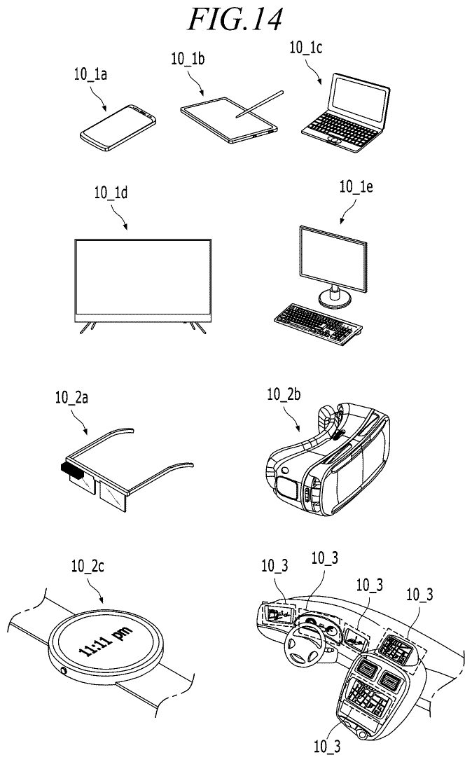

FIG. 14 shows schematic views of an embodiment of electronic devices according to various embodiments of the disclosure. Referring to FIG. 14, various electronic devices to which the display device in the embodiments is applied may include not only image-displaying electronic devices such as a smartphone 10_1a, a tablet personal computer (“PC”) 10_1b, a laptop computer 10_1c, a television (“TV”) set 10_1d, and a desktop monitor 10_1e, but also wearable electronic devices including a display module, such as smart glasses 10_2a, a head-mounted display device 10_2b, and a smartwatch 10_2c. The display device may also be applied to vehicle electronic devices 10_3 including a display module, such as a vehicle instrument panel, a center fascia, a dashboard-integrated center information display (“CID”), and a room mirror display.

Hitherto, certain preferred embodiments of the disclosure have been described above, but these are merely and are not intended to limit the disclosure. Those skilled in the art to which the disclosure pertains may make various modifications and changes to the embodiments by adding, changing, deleting, or adding certain elements, without departing from the scope of the technical ideas of the disclosure as set forth in the claims, and such modifications and changes should also be regarded as being within the scope of the disclosure.

What is claimed is:

1. A display device comprising:
a substrate;
a circuit layer disposed on the substrate;
a light-emitting diode layer disposed on the circuit layer and comprising a light-emitting diode and a pixel defining layer, the pixel defining layer defining an aperture in which the light-emitting diode is disposed;
an encapsulation layer disposed on the light-emitting diode layer and comprising at least one of an inorganic film and an organic film;
a color filter disposed on the encapsulation layer;
a light-shielding portion disposed on the encapsulation layer and providing an aperture in which the color filter is disposed; and
a scattering layer disposed on the light-shielding portion and the color filter and exposing at least a portion of the color filter, the scattering layer comprising scattering particles,
wherein the scattering layer overlaps with the pixel defining layer, and
wherein at least a portion of the scattering layer does not overlap with the pixel defining layer and overlaps with the color filter.

2. The display device of claim 1, wherein the scattering layer overlaps with the light-shielding portion, and at least a portion of the scattering layer does not overlap with the light-shielding portion and overlaps with the color filter.

3. The display device of claim 2, wherein the pixel defining layer overlaps with the light-shielding portion, and at least a portion of the pixel defining layer does not overlap with the light-shielding portion.

4. The display device of claim 1, wherein the scattering layer is thickest in a region overlapping with the light-shielding portion and non-overlapping with the color filter.

5. The display device of claim 4, wherein a maximum thickness of the scattering layer in the region overlapping with the light-shielding portion is greater than a maximum thickness of the scattering layer in the region overlapping with the color filter.

6. The display device of claim 1, wherein the color filter has a convex shape protruding in a display direction on the encapsulation layer.

7. The display device of claim 1, wherein the scattering layer has a convex shape protruding in a display direction on the light-shielding portion and the color filter.

8. The display device of claim 1, wherein the scattering particles comprise at least one of TiO₂, SiO₂, ZrO₂, HfO₂, ZnO, Al₂O₃, silica, and polymer particles.

9. A method for manufacturing a display device, the method comprising:
preparing a preliminary display panel by forming a circuit layer, a light-emitting diode layer, and an encapsulation layer on a substrate, the light-emitting diode layer comprising a light-emitting diode and a pixel defining layer which defines an aperture in which the light-emitting diode is disposed;
forming a light-shielding portion on the encapsulation layer, the light-shielding portion providing an aperture;
forming a color filter in the aperture of the light-shielding portion on the encapsulation layer; and
forming a scattering layer on the light-shielding portion and the color filter, the scattering layer exposing at least a portion of the color filter,
wherein the scattering layer comprises scattering particles,
wherein the scattering layer overlaps with the pixel defining layer, and
wherein at least a portion of the scattering layer does not overlap with the pixel defining layer and overlaps with the color filter.

10. The method of claim 9, wherein the forming the color filter comprises ejecting and curing color filter ink including a pigment or dye to form the color filter in the aperture of the light-shielding portion.

11. The method of claim 10, wherein the forming the scattering layer comprises patterning a composition including the scattering particles using a photoresist to form the scattering layer.

12. The method of claim 10, wherein the forming the scattering layer comprises ejecting and curing ink including the scattering particles to form the scattering layer.

13. The method of claim 9, wherein the forming the color filter comprises patterning a color filter composition including a pigment or dye using a photoresist to form the color filter in the aperture of the light-shielding portion.

14. The method of claim 13, wherein the forming the scattering layer comprises patterning a composition including the scattering particles using a photoresist to form the scattering layer.

15. The method of claim 9, wherein the scattering layer overlaps with the light-shielding portion, and
at least a portion of the scattering layer does not overlap with the light-shielding portion and overlaps with the color filter.

16. The method of claim 15, wherein the light-shielding portion overlaps with the pixel defining layer, and
at least a portion of the pixel defining layer does not overlap with the light-shielding portion.

17. The method of claim 9, wherein the scattering layer is thickest in a region overlapping with the light-shielding portion and non-overlapping with the color filter.

18. The method of claim 17, wherein a maximum thickness of the scattering layer in the region overlapping with the light-shielding portion is greater than a maximum thickness of the scattering layer in the region overlapping with the color filter.

19. The method of claim 9, wherein the scattering particles comprise at least one of TiO₂, SiO₂, ZrO₂, HfO₂, ZnO, Al₂O₃, silica, and polymer particles.

20. An electronic device comprising:
a display module configured to output image information based on an image data signal, the display module comprising:
a substrate;
a circuit layer disposed on the substrate;
a light-emitting diode layer disposed on the circuit layer and comprising a light-emitting diode and a pixel defining layer, the pixel defining layer defining an aperture in which the light-emitting diode is disposed;
an encapsulation layer disposed on the light-emitting diode layer and comprising at least one of an inorganic film and an organic film;
a color filter disposed on the encapsulation layer;
a light-shielding portion disposed on the encapsulation layer and providing an aperture in which the color filter is disposed; and
a scattering layer disposed on the light-shielding portion and the color filter and exposing at least a portion of the color filter, the scattering layer comprising scattering particles;
a processor configured to execute an application to transfer the image data signal to the display module;
a memory configured to store data information for executing the application; and
a power module configured to supply power to the display module, the processor, and the memory,
wherein the scattering layer overlaps with the pixel defining layer, and
wherein at least a portion of the scattering layer does not overlap with the pixel defining layer and overlaps with the color filter.
